(19) United States
(12) Patent Application Publication
(10) Pub. No.: US 2003/0145791 A1
(43) Pub. Date: Aug. 7, 2003

(54) Thermal processing apparatus

(75) Inventors: Hiroshi Shinya, Kumamoto-ken (JP); Takahiro Kitano, Kumamoto-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo-To (JP)

(21) Appl. No.: 10/359,245

(22) Filed: Feb. 6, 2003

(30) Foreign Application Priority Data
Feb. 7, 2002 (JP) 2002-030360

(51) Int. Cl. C23C 16/00

(52) U.S. Cl. 118/724; 118/712

(57) ABSTRACT

A thermal processing apparatus for applying thermal processing to a substrate having a processed film thereon has a discharger for discharging process gas from a processing chamber and a ceiling plate provided between the substrate and the discharger, having apertures at different aperture ratios in accordance with distances from the center of the ceiling plate. The apparatus may have dischargers, provided over concentric circles of the substrate, for discharging process gas from the processing chamber and discharging-amount adjusters each for adjusting a discharging amount of the corresponding discharger. The apparatus may have gas suppliers, provided over the concentric circles of the substrate, for supplying process gas into the processing chamber and supply-amount adjusters each for adjusting a supply amount of the corresponding supplier. Instead of the dischargers and the suppliers, the apparatus may have supply and discharging units for supplying and discharging process gas into and from the processing chamber, a switch for switching the supply and discharging units between the supplying and discharging of the process gas and supply-amount adjusters each for adjusting a supply amount of the corresponding supply and discharging unit; and discharging-amount adjusters each for adjusting a discharging amount of the corresponding supply and discharging unit.

### FIELD OF THE INVENTION

The present invention relates to a thermal processing apparatus with film-quality controllability for resist films formed on substrates such as semiconductor wafers.

### BACKGROUND OF THE INVENTION

Photolithographic techniques in the manufacture of semiconductor wafers and LCD substrates, etc., (called wafers hereinafter) include the following steps.

A resist solution is supplied (sprayed and applied) on a wafer to form a resist film thereon (resist-film forming process). The resist film is then exposed to a circuit pattern (exposing process). A developing solution is supplied (sprayed and applied) on the exposed wafer (developing process).

Several heating processes are carried out between these processes: such as, a prebaking (PAB) process to evaporate solvent remaining in the resist film for high adhesion between the wafer and the resist film, between the resist-film forming process and the exposing process; a post-exposure baking (PEB) process to prevent formation of fringes and/or induce acid-catalytic reaction in chemical-amplifying-type resist, between the exposing process and the developing process; and a postbaking (POB) process to remove solvent remaining in the resist and/or a rinse solution absorbed in the resist during the developing process for better soaking in wet etching, after the developing process.

As microfabrication of circuit patterns having fine line width (CD) has advanced, higher uniformity of on-wafer pattern width has been required in these photolithographic processes. Thus, the causes of pattern-width variation should be eliminated from processes before the exposing process, in addition to, the developing and PEB processes that have thought to be big causes of pattern-width variation.

Generally, such pattern-width variation has been solved with high uniformity of resist-film thickness.

It has, however, been found that pattern-width variation is further caused by change in film quality due to chemical or physical variations in resist films. The resist-film chemical or physical variations are, for example, variation in amount of resist components such as solvent remaining in resist films, variation in protecting-group proportion and variation in state of polymer in resist.

Under consideration of these factors, higher uniformity of resist-film thickness is required for solving pattern-width variation.

It has been found that variation in amount of solvent remaining in resist films mainly occurs during the resist-film forming process and the PAB process.

### SUMMARY OF THE INVENTION

A purpose of the present invention is to provide a thermal processing apparatus with controllability of the amount of solvent remaining in resist films during a prebaking process for high uniformity of resist-film thickness.

The present invention provides a thermal processing apparatus including a processing chamber containing a heat source and a table for a substrate having a processed film thereon to be placed thereon, comprising: a discharger for discharging process gas from the processing chamber; and a ceiling plate provided between the substrate and the discharger, having apertures at different aperture ratios in accordance with distances from the center of the ceiling plate.

Moreover, the present invention provides a thermal processing apparatus including a processing chamber containing a heat source and a table for a substrate having a processed film thereon to be placed thereon, comprising: a plurality of dischargers, provided over concentric circles of the substrate, for discharging process gas from the processing chamber; and a plurality of discharging-amount adjusters each for adjusting a discharging amount of the corresponding discharger.

Moreover, the present invention provides a thermal processing apparatus including a processing chamber containing a heat source and a table on which a substrate having a processed film thereon is to be placed, comprising: a plurality of dischargers, provided over concentric circles of the substrate, for discharging process gas from the processing chamber; a plurality of gas suppliers, provided over the concentric circles of the substrate, for supplying process gas into the processing chamber; a plurality of discharging-amount adjusters each for adjusting a discharging amount of the corresponding discharger; and a plurality of supply-amount adjusters each for adjusting a supply amount of the corresponding supplier.

Furthermore, the present invention provides a thermal processing apparatus including a processing chamber containing a heat source and a table for a substrate having a processed film thereon to be placed thereon , comprising: a plurality of supply and discharging units, provided over concentric circles of the substrate, for supplying and discharging process gas into and from the processing chamber; a switch for switching the supply and discharging units between the supplying and discharging of the process gas; a plurality of supply-amount adjusters each for adjusting a supply amount of the corresponding supply and exhaust unit; and a plurality of discharging-amount adjusters each for adjusting a discharging amount of the corresponding supply and discharging unit.

### BRIEF DESCRIPTION OF DRAWINGS

FIG. 1 is a schematic plan view showing a resist-film applying and developing system equipped with a thermal processing apparatus according to the present invention;

FIG. 2 is a schematic front view showing the resist-film applying and developing system;

FIG. 3 is a schematic rear view showing the resist-film applying and developing system;

FIG. 4 is a schematic illustration of a prebake (PB) unit;

FIG. 5 is a schematic illustration of a first embodiment of the thermal processing apparatus according to the present invention;

FIG. 6 is a schematic plan view showing a ceiling plate in the first embodiment of the thermal processing apparatus according to the present invention;

FIG. 7 is a schematic illustration of a second embodiment of the thermal processing apparatus according to the present invention;

FIG. 8 is a schematic plan view showing an exhaust mechanism in the second embodiment of the thermal processing apparatus according to the present invention; and

FIG. 9 is a schematic illustration of a third embodiment of the thermal processing apparatus according to the present invention.

### DETAILED DESCRIPTION OF PREFERRED EMBODIMENTS

Preferred embodiments according to the present invention will be disclosed with reference to the attached drawings.

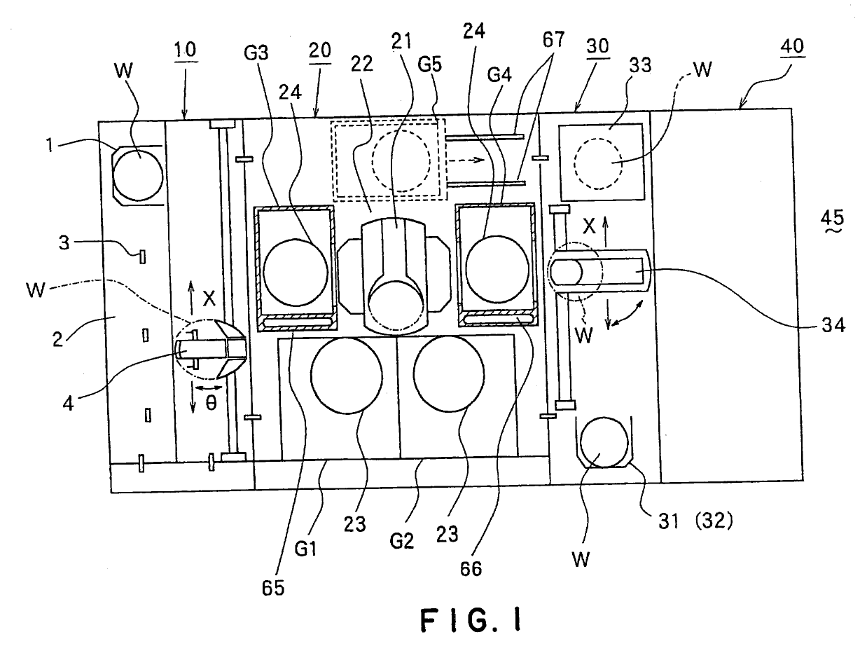

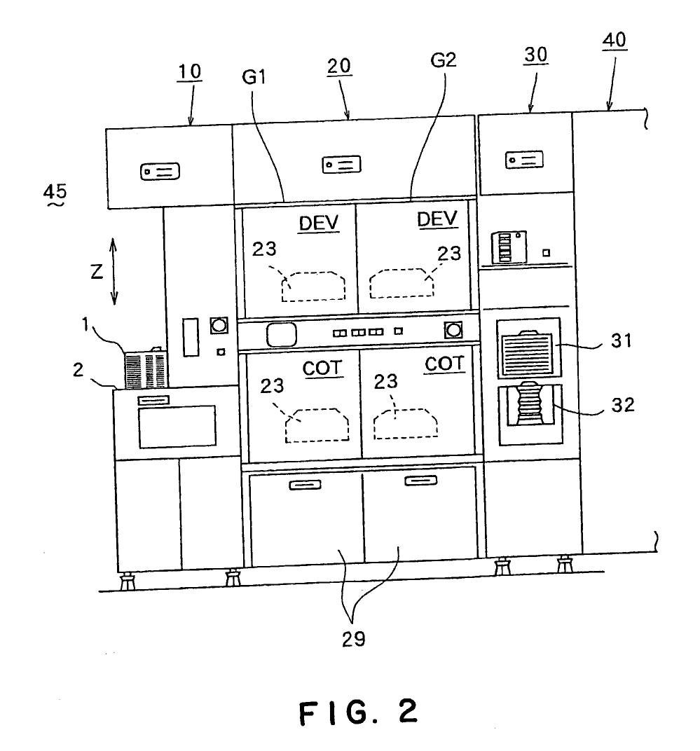

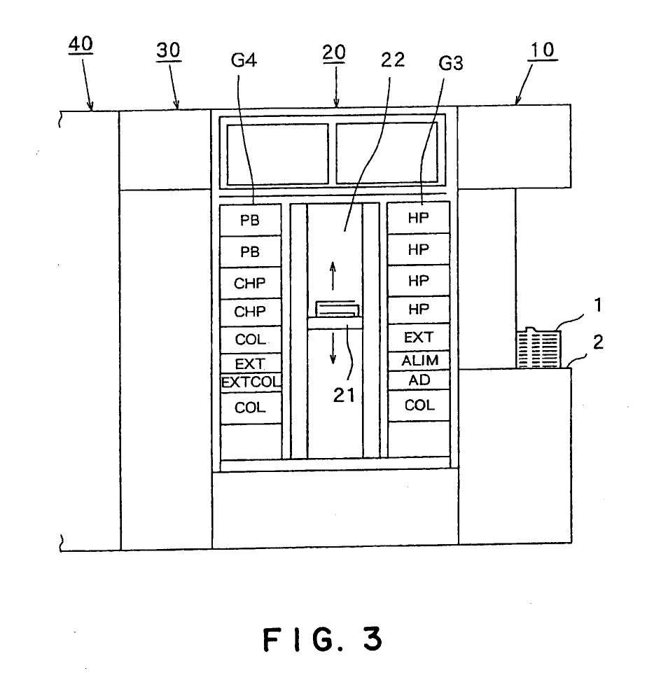

FIG. 1 is a schematic plan view showing a resist-film applying and developing system equipped with a thermal processing apparatus according to the present invention. FIGS. 2 and 3 are schematic front and rear views, respectively, showing the resist-film applying and developing system.

The resist-film applying and developing system is mainly equipped with: a cassette station (transfer section) 10 for receiving and transferring semiconductor wafers (called wafers) W as substrates, such as, 25 wafers contained in each wafer cassette 1; a processing section 20 installed therein in multistage being several types of processing units for applying several types of process to each wafer W; and an interface section 30 for receiving and transferring wafers W from and to an exposing (EXP) unit 40 provided in the vicinity of the processing section 20.

As shown in FIG. 1, for example, four wafer cassettes 1 are aligned at protrusions 3 on a cassette table 2 in a direction of X as facing the processing section 20.

Provided on the cassette station 10 is a pair of wafer-transfer tweezers 4 movable to access any cassette 1 in the cassette-aligned direction (direction X) and also another cassette-aligned direction (direction Z) in which wafers W are stack up in the wafer cassettes 1.

The wafer-transfer tweezers 4 are also rotatable in a horizontal direction Θ for transferring wafers W to an alignment (ALIM) unit and an extension (EXT) unit of a multi-stage third processing-unit group G3 (described below) in the processing section 20.

A vertical-transfer-type main wafer-transfer mechanism 21 is provided in a chamber 22 in the center of the processing section 20, as shown in FIG. 1. All processing units are arranged around the chamber 22. There are five processing-unit groups G1, G2, G3, G4 and G5 each having multi-stage processing units.

In FIG. 1, the first and second processing-unit groups G1 and G2 are aligned in the front section of the system, the third processing-unit group G3 is set in the vicinity of the cassette station 10, and the fourth processing-unit group G4 is set in the vicinity of the interface section 30. The fifth processing-unit group G5 is an optional unit group that can be set in the rear section of the system.

As shown in FIG. 2, stack in the first unit group G1 are two spinner processing units for processing each wafer W set in a cap (processing container) 23 with a spin chuck, such as, a resist-coating (COT) unit for supplying a resist solution on the wafer W to form a resist film thereon and a developing (DEV) unit for supplying a developing solution on the wafer W for a developing process. The same processing units, such as, the COT and DEV units are stack in the second unit group G2. The COT unit is set at the lower stage in each of the unit groups G1 and G2, in FIG. 2, for simple structure and maintenance in disposal of resist solution. It can, however, be set at the upper stage if necessary.

As shown in FIG. 3, stack in the third unit group G3 are, for example, eight open-type processing units for processing each wafer W set in a table 24 (FIG. 1), such as, a cooling (COL) unit for cooling the wafer W, an adhesion (AD) unit for applying a hydrophobic process to the wafer W, an alignment (ALIM) unit for wafer alignment, an extension (EXT) unit for wafer reception and transfer, and four hot-plate (HP) units for baking the wafer W.

Moreover, stack in the fourth processing-unit group G4 are also, for example, eight open-type processing units, such as, a COL unit, an extension cooling (EXTCOL) unit, an EXT unit, another COL unit, two chilling hot-plate (CHP) units, and two prebaking (PB) units for prebaking each resist-formed wafer W.

Among the processing units, the COL and EXTCOL units for low-temperature processing are set at the lower stages whereas the HP, CHP and PB units for high-temperature processing are set at the upper stages, for less thermal interference between the units. These units can, however, be stack randomly.

In the processing station 20, shown in FIG. 1, ducts 65 and 66 are provided vertically in the side walls of the third and fourth (open-type) processing-unit groups G3 and G4, respectively, in the vicinity of the first and second (spinner) processing-unit groups G1 and G2. Flowing through the ducts 65 and 66 is down flow of clean air or temperature-adjusted air. This duct structure will block heat generated in each of the units G3 and G4 so that heat cannot be transferred to the spinner processing units G1 and G2.

The processing system can further be equipped with the fifth multi-stage processing-unit group G5 at the back of the main wafer-transfer mechanism 21, as illustrated by dot lines in FIG. 1. The unit group G5 is slidable by guide rails 67 along the transfer mechanism 21. This slidable mechanism offers enough space for maintenance operations to the transfer mechanism 21 at the back thereof.

The interface section 30 is equal to the processing station 20 in length but smaller than the latter in width. Provided in the front of the interface section 30 are a movable pickup cassette 31 and a fixed buffer cassette 32 stack in two stages. On the other hand, provided in the back and center of the interface section 30 are a peripheral-exposing unit 33 and a wafer transfer arm 34, respectively.

The wafer transfer arm 34 is movable in the directions X and Z for wafer transfer to the pickup and buffer cassettes 31 and 32 and also the peripheral-exposing unit 33. It is also rotatable in the direction Θ for wafer transfer to the EXT unit of the fourth processing-unit group G4 in the processing station 20 and also to a wafer table (not shown) on the next exposing (EXP) unit 40.

The processing system described above is installed in a clean room 45 (FIG. 1) for high cleanliness. Not only that, a vertical laminar-flow system is installed in the system for higher cleanliness.

In operation, the wafer-transfer tweezers 4 access a cassette 1 containing pre-processed wafers W set on the cassette table 2 and pick up one wafer W, in the cassette station 10. The tweezers 4 move to the ALIM unit of the third processing-unit group G3 and place the wafer W on the wafer table 24 in the ALIM unit 24 for orientation-flat positioning and centering.

The main wafer-transfer mechanism 21 then accesses the ALIM unit from the other side to receive the wafer W placed on the wafer table 24 and transfers it to the AD unit in third processing-unit group G3 for wafer hydrophobic processing.

On completion of hydrophobic processing, the main wafer-transfer mechanism 21 takes out the wafer W from the AD unit and transfers it to a COL unit in the third or the fourth processing-unit group G3 or G4 for cooling the wafer W to a set temperature such as 23° C. before resist coating.

The main wafer-transfer mechanism 21 takes out the wafer W from the COL unit on completion of cooling and transfers it to a COT unit in the first or the second unit group G1 or G2 for applying resist over the wafer W at a uniform film thickness by spin coating.

On completion of coating, the main wafer-transfer mechanism 21 takes out the wafer W from the COT unit and transfers it to a PB unit in the third or the fourth processing-unit group G3 or G4 for prebaking for a predetermined period at a set temperature such as 100° C., to evaporate solvent remaining in the coating film on the wafer W.

The main wafer-transfer mechanism 21 takes out the wafer W from the PB unit on completion of prebaking and transfers it to the EXTCOL unit in the fourth processing-unit group G4 for cooling the wafer W to a set temperature such as 24° C. suitable for the next peripheral exposure in the peripheral exposing unit 33.

After this cooling process, the main wafer-transfer mechanism 21 takes out the wafer W from the EXTCOL unit and transfers it to the EXT unit just above the EXTCOL unit. When the wafer W is set on a table (not shown) in the EXTCOL unit, the wafer-transfer arm 34 of the interface station 30 accesses the EXTCOL-unit table from the other side, receives the wafer W and transfer it to the peripheral exposing unit 33 for peripheral exposure on the wafer edges. Film-thickness measuring equipment may be installed in the exposing unit 33 for periodical wafer-film-thickness (or -quality) uniformity check.

On completion of peripheral exposure, the wafer-transfer arm 34 transfers the wafer W from the peripheral exposing unit 33 to a wafer table (not shown) on the adjacent EXP unit 40. The wafer W may, however, be stored once in the buffer cassette 32 before transferred to the exposing unit 33.

When the wafer W is returned to the wafer table on the EXP unit 40 on completion of exposure over the entire wafer surface, the wafer-transfer arm 34 accesses the wafer table to receive the wafer W and transfers it to the EXT unit in the forth processing-unit group G4 in the processing station 20. The wafer W may also be stored once in the buffer cassette 32 before transferred to the processing station 20.

The wafer W set on a wafer table in the EXT unit is transferred by the main wafer-transfer mechanism 21 to the CHP unit for post-exposure baking (PEB) processing to prevent fringe formation or induce acid catalysis with a chemical-amplified resist (CAR).

The wafer W is then transferred to the DEV unit in the first or the second processing-unit group G1 or G2. A developing solution is, for example, sprayed over the resist on the wafer W set on the spin chuck in the DEV unit. On completion of development, a cleaning solution is pored over the wafer W to wash away the developing solution.

On completion of development, the main wafer-transfer mechanism 21 transfers the wafer W from the DEV unit to an HP unit in the third or the fourth processing-unit group G3 or G4 for postbaking for a predetermined period at a set temperature such as 100° C. to harden the resist swelled due to development for enhanced chemical resistance.

The main wafer-transfer mechanism 21 takes out the wafer W from the HP unit on completion of postbaking and transfers it to any COL unit in the third or the fourth unit group G3 or G4.

Once the wafer W has been cooled to an ambient temperature, it is transferred by the main wafer-transfer mechanism 21 to the EXT unit in the third processing-unit group G3. The wafer-transferring tweezers 4 access the EXT unit from the other side to receive the wafer W set on a wafer table (not shown) in the EXT unit.

The wafer-transferring tweezers 4 transfer the wafer W to a cassette 1 for containing already-processed wafers and insert it into a wafer-receiving slot in the cassette 1, thus finishing the procedure.

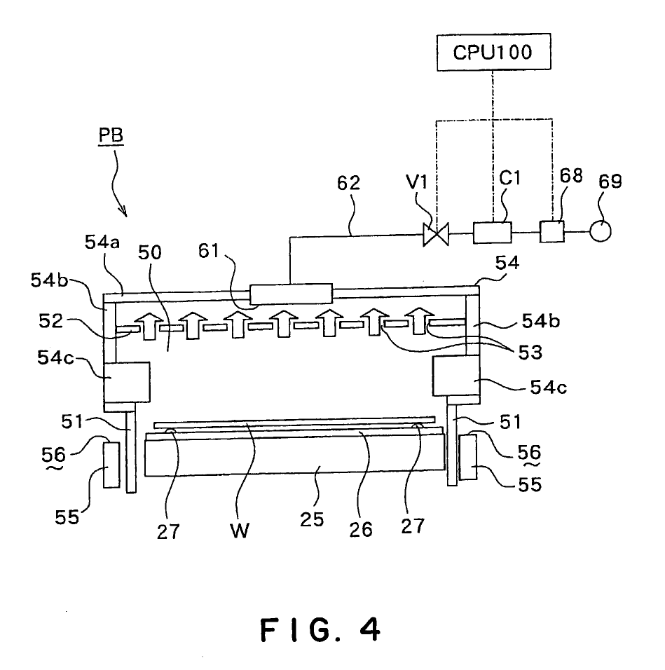

Disclosed next with reference to FIG. 4 is the prebaking (PB) unit as an embodiment of the thermal processing apparatus according to the present invention.

The PB unit has a processing chamber 50 with a container 55 and a cover 54. Provided in the chamber 50 are a wafer table 25 and supporting pins (not shown) for elevating each wafer W on the table 25.

Provided between the container 55 and the cover 54 are an opening 56 for wafer transfer between the supporting pins and the main wafer-transfer mechanism 21 and also a shutter 51 for isolating the processing chamber 50 from the outside air.

The cover 54 consists of a circular top section 54a with an exhaust opening 61 at the center, through which process gas will be discharged from the processing chamber 50, a side-wall section 54b extending from the outer edges of the top section 54a, and a contact section 54c that will touch the shutter 51, as described blow.

The exhaust opening 61 is connected to an exhaust system 69 through an exhaust pipe 62. Provided along the pipe 62 are an exhaust mechanism for negative-pressure generation such as an ejector 68, a mass-flow controller C1 for measuring the amount of gas (flow rate) discharged through the exhaust opening 61, and a valve V1. The ejector 68, the controller C1 and the valve V1 are connected to a CPU 100 (controller) for adjustments to gas discharging amount (flow rate) under control by a control signal from the CPU 100.

Provided at the side-wall section 54b under the exhaust opening 61 is a circular diffuser plate 52 with pores 53 for preventing turbulence of discharging gas just under the exhaust opening 61.

The wafer table 25 is a circular table larger than wafers W, having a hot plate 26 thereon for heating each wafer W. The hot plate 26 is made of a heat-conducting material such as aluminum alloy, with a built-in heater (not shown). Mounted on the table 25 are gap pins 27 for supporting each wafer W with a gap between the wafer W and the hot plate 26, for prevention of particle attachment to the wafer W. Provided further on the table 25 are, for example, three holes (not shown) at a concentric circle so that the supporting pins can appear through the holes.

The shutter 51 can be elevated by an elevating cylinder (not shown) to touch stoppers (not shown) in the contact section 54c of the cover 54 to achieve high airtightness.

In operation, the shutter 51 is opened, and each wafer W is transferred into the PB unit by the main wafer-transfer mechanism 21. The wafer W is passed to the supporting pins and then placed on the gap pins on the table 25 while the supporting pins are descending.

The hot plate is heated to evaporate solvent the remaining in the resist film formed on the wafer W after the shutter 51 is closed. The valve V1 is opened and the ejector 68 is operated by the control signal from the CPU 100 to start gas discharging while the discharging amount (flow rate) is being adjusted by the mass-flow controller C1.

On gas discharging through the exhaust opening 61, the chamber 50 is decompressed so that vapors of solvent on the wafer W evaporated by the hot plate 26 can be discharged through the opening 61.

On completion of wafer-heating process, the valve V1 is closed and then the ejector 68 and the mass-flow controller C1 are turned off by the control signal from the CPU 100.

The processed wafer W is then elevated by the supporting pins and taken out by the main wafer-transfer mechanism 21 through the exhaust opening 56.

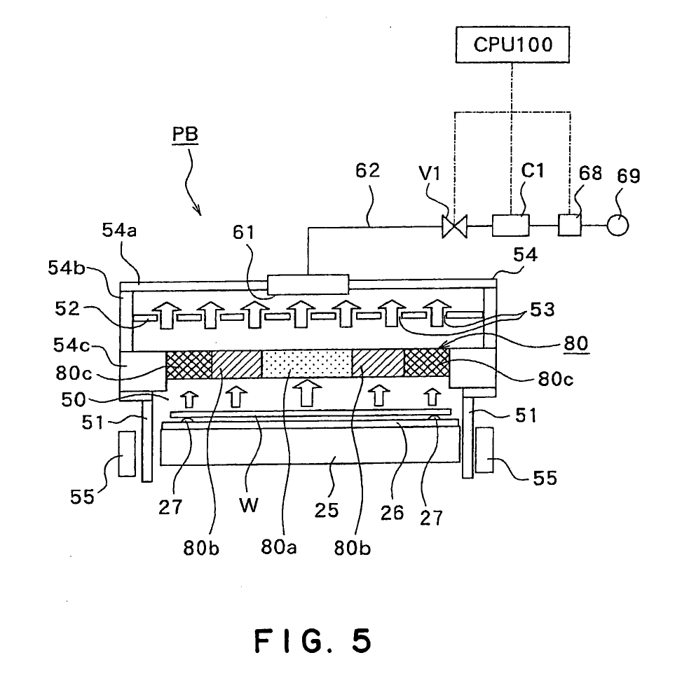

Disclosed in detail with reference to FIGS. 5 to 9 are several embodiments in which the thermal processing apparatus is employed for the PB unit described above.

(First Embodiment)

The first embodiment according to the present invention is equipped with a ceiling plate 80 between each wafer W and the exhaust opening 61. The ceiling plate 80 is provided with many apertures of different aperture ratios on several concentric circles (in accordance with the distance from the center), to adjust discharging amount (flow rate) for control of solvent evaporation rate.

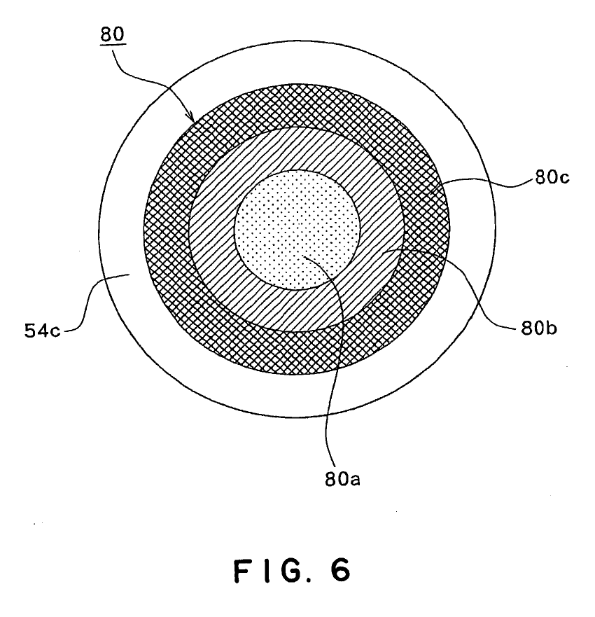

The ceiling plate 80 is made of a porous material such as SiC with an aperture ratio of about 20 to 50%. In detail, as shown in FIGS. 5 and 6, the ceiling plate 80 may be made of a porous material 80a with an aperture ratio of 40 to 50% at the inner section, a porous material 80b with an aperture ratio of 30 to 40% at the middle section and also a porous material 80c with an aperture ratio of 20 to 30% at the outer section. This combination of materials is preferable when the solvent evaporation rate is lower at the wafer center than the wafer edges.

Moreover, the ceiling plate 80 is provided to face each wafer W under the diffuser plate 52, fixed to the inner wall of the contact section 54c of the cover 54. The distance between the lower surface of the ceiling plate 80 and the wafer surface is adjusted in the range from about 1 to 20 mm.

The PB unit having such mechanism disclosed above provides uniformity for the amount of solvent remaining on each wafer W. This is because process gas can more easily pass through the inner section than the middle and outer sections of the ceiling plate 80. In other words, the ceiling plate 80 allows quick discharging of solvent evaporating from the resist film by a thermal process, thus decreasing solvent density in the chamber 50, which achieves higher evaporation rate at the wafer inner section than the middle and outer section for uniform amount of solvent remaining on each wafer W.

The above disclosure offers higher aperture ratio at the inner section than the middle and outer sections of the ceiling plate 80. The aperture ratio can, however, be freely set in accordance with solvent evaporation rate. For example, the aperture ratio may be set lower at the inner section than the middle and outer sections when the solvent evaporation rate is higher at the wafer center than the wafer edges.

Moreover, not only the porous material, the ceiling plate 80 may be made of other materials, such as, aluminum or stainless steel with apertures of different numbers and/or sizes on several concentric circles, for allowing solvent vapors passing therethrough or combination of metal and porous materials.

(Second Embodiment)

The second embodiment according to the present invention is applied to a prebake (PB) unit equipped with several exhaust openings 61A, 61B and 61C over the several concentric circles on each wafer W to adjust the discharging amount (flow rate) to achieve evaporation-rate controllability to solvent remaining on the wafer W.

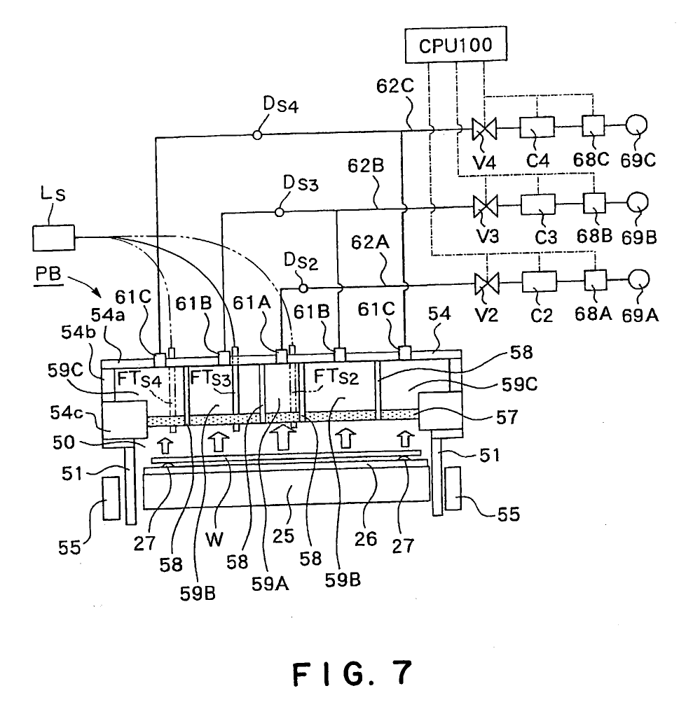

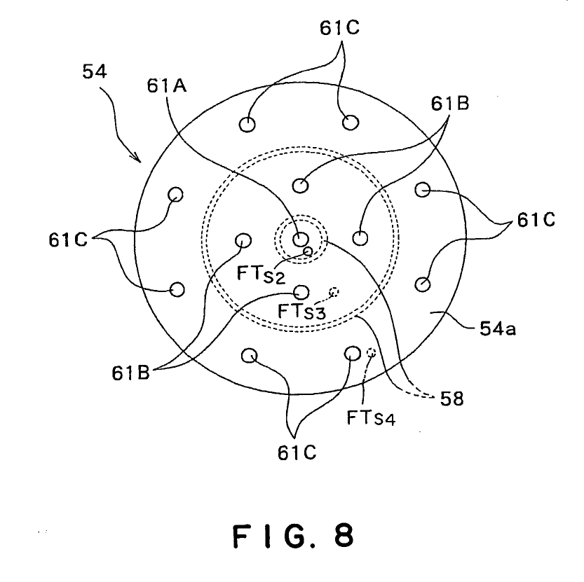

As shown in FIGS. 7 and 8, the exhaust openings 61A, 61B and 61C are arranged on the several concentric circles on the circular top section 54a and separated by partitions 58. Each partition 58 extends from the top section 54a to a diffuser plate 57 made of a porous material or with many punch holes held by the contact section 54c for pressure uniformity on each wafer W.

Also separated by the partitions 58 under the exhaust openings 61A, 61B and 61C are buffers 59A, 59B and 59C made of a porous material for prevention of turbulence of discharging gas just under the openings, to achieve pressure uniformity on the several concentric circles on the wafer W. The distance between the lower surface of the diffuser plate 57 and the surface of the wafer W is adjusted in the range from about 1 to 20 mm.

The exhaust openings 61A, 61B and 61C are connected to exhaust systems 69A, 69B and 69C through exhaust pipes 62A, 62B and 62C, respectively, for discharging process gas from the processing chamber 50. Provided along the pipes 62A, 62B and 62C are exhaust mechanisms for negative-pressure generation such as ejectors 68A, 68B and 68C, mass-flow controllers C2, C3 and C4 for measurements of and adjustments to the amount of gas (flow rate) discharged through the openings 61A, 61B and 61C, and valves V2, V3 and V4, respectively.

The ejectors 68A, 68B and 68C, the controllers C2, C3 and C4 and the valves V2, V3 and V4 are connected to the CPU 100 for adjustments to gas discharging amount (flow rate) under control by a control signal from the CPU 100.

Provided in the exhaust pipes 62A, 62B and 62C are density sensors Ds2, Ds3 and Ds4, respectively, as shown in FIG. 7, for detecting the density of resist solvent. These sensors may be installed in the buffers 59A, 59B and 59C.

Instead of the density sensors Ds2, Ds3 and Ds4, an optical film-thickness sensor FTs3 may be provided as illustrated in FIGS. 7 and 8 with a light source Ls, to detect an average film thickness of a resist film formed on each wafer W. Several optical film-thickness sensors such as FTs2 and FTs4 shown in FIGS. 7 and 8 may be provided for examining wafer-surface film-thickness distribution (on-wafer X-axis profile). Although not shown, the film-thickness sensors may be electrically connected to the CPU 100.

The PB unit in the second embodiment achieves control of evaporation rate of solvent remaining on each wafer W with control of gas discharging amount (flow rate) in accordance with resist-solvent density detected by the density sensors Ds2, Ds3 and Ds4 or the film thickness detected by the film-thickness sensors FTs2, FTs3 and FTs4.

In detail, for example, the gas discharging amount (flow rate) on the wafer center region is made larger than on the wafer outer region when an evaporating rate of solvent remaining on the center region of each wafer W under thermal processing is lower than on the outer region of the wafer W.

This discharge-amount control allows quick discharge of the solvent from the processing chamber 50, to decrease the solvent density in the chamber, thus achieving uniformity of solvent remaining on the wafer W with high solvent-evaporation rate on the wafer center region.

The discharge-amount control with the optical film-thickness sensors FTs2, FTs3 and FTs4 may be performed as follows:

Film thicknesses detected by the optical film-thickness sensors FTs2, FTs3 and FTs4 are sent to the CPU 100 and compared with prestored data on film-thicknesses variation in time from the process-staring time. The CPU 100 then sends a control signal to the ejectors 68A, 68B and 68C, the controllers C2, C3 and C4 and the valves V2, V3 and V4 so that the gas discharging amount (flow rate) on the wafer region on which a thick film has been formed is made larger whereas that on the wafer region on which a thin film has been formed is made smaller, for uniformity of thickness over the wafer surface.

(Third Embodiment)

The third embodiment according to the present invention is applied to a prebake (PB) unit equipped with several supply and exhaust openings 81A, 81B and 81C for supplying and discharging process gas to and from the buffers 59A, 59B and 59C provided in the processing chamber 50, the gas supplying and discharging amounts (flow rates) being adjustable for control of evaporation rate of solvent remaining on each wafer W.

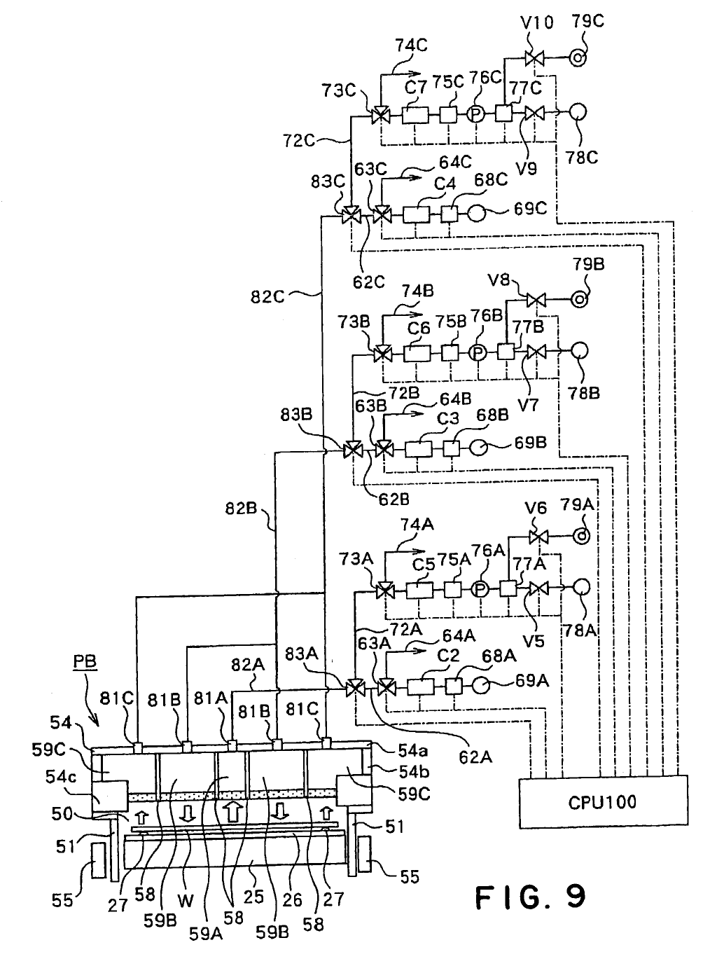

As shown in FIG. 9, like the exhaust openings 61A, 61B and 61C (second embodiment), the supply and exhaust openings 81A, 81B and 81C are arranged on the several concentric circles on the circular top section 54a and separated by the partitions 58. Each partition 58 extends from the top section 54a to the diffuser plate 57 made of a porous material or with many punch holes held by the contact section 54c for pressure uniformity on each wafer W.

Also separated by the partitions 58 under the supply and exhaust openings 81A, 81B and 81C are the buffers 59A, 59B and 59C made of a porous material for prevention of turbulence of discharging gas just under the openings, to achieve pressure uniformity on the several concentric circles on the wafer W.

The supply and exhaust openings 81A, 81B and 81C are connected to three-way valves 83A, 83B and 83C through purge pipes 82A, 82B and 82C, respectively, for discharging resist solvent from the PB unit. The three-way valves 83A, 83B and 83C are connected to the exhaust pipes 62A, 62B and 62C and gas supply pipes 72A, 72B and 72C, respectively.

The three-way valves 83A, 83B and 83C switch the exhaust pipes 62A, 62B and 62C, and the gas supply pipes 72A, 72B and 72C, for supply or discharging through the supply and exhaust openings 81A, 81B and 81C, respectively.

Like the second embodiment, the exhaust pipes 62A, 62B and 62C are connected to the exhaust systems 69A, 69B and 69C for discharging process gas from the processing chamber 50, provided with the exhaust mechanisms for negative-pressure generation such as the ejectors 68A, 68B and 68C, the mass-flow controllers C2, C3 and C4 for measurements of and adjustments to the amount of gas (flow rate) discharged through the supply and exhaust openings 81A, 81B and 81C, and the valves V2, V3 and V4, respectively.

Other three-way valves 63A, 63B and 63C are provided between the three-way valves 83A, 83B and 83C and the mass-flow controllers C2, C3 and C4, respectively. The valves 63A, 63B and 63C are switched to bypass pipes 64A, 64B and 64C while process gas is not being discharged from the processing chamber 50, to prevent the exhaust pipes 62A, 62B and 62C from being sealed up.

The gas supply pipes 72A, 72B and 72C are connected to three-way valves 73A, 73B and 73C, respectively, that are switched to bypass pipes 74A, 74B and 74C while process gas is not being supplied to the processing chamber 50, to prevent the supply pipes 72A, 72B and 72C from being sealed up.

The three-way valves 73A, 73B and 73C are connected to mass-flow controllers C5, C6 and C7, respectively, for gas supply-amount (flow-rate) measurements and adjustments, which are further connected to temperature adjusters 75A, 75B and 75C for gas-temperature adjustments, pressure adjusters (regulators) 76A, 76B and 76C for gas-pressure adjustments and mixers 77A, 77B and 77C for solvent-density adjustments to process gas, respectively.

The mixers 77A, 77B and 77C are connected to gas supply sources 78A, 78B and 78C via valves V5, V7 and V9, respectively, and also to solvent supply sources 79A, 79B and 79C via valves V6, V8 and V10, respectively. Solvent for wafer resist films supplied by the supply sources 79A, 79B and 79C are evaporated into inert gas by a heater (not shown) with a temperature-adjusting function to generate solvent gas. The density of solvent contained in the solvent gas is adjusted by a density control valve (not shown).

The three-way valves 83A, 83B and 83C are connected to the CPU 100 for switching between the exhaust pipes 62A, 62B and 62C, and the supply pipes 72A, 72B and 72C during thermal processing under a control signal based on a program prestored in the CPU 100.

Also connected to the CPU 100 are the ejectors 68A, 68B and 68C, the mass-flow controllers C2 to C7, the three-way valves 63A, 63B and 63C, and 73A, 73B and 73C, the pressure adjusters 76A, 76B and 76C, the mixers 77A, 77B and 77C, and the valves V5 to V10, for adjustments to gas supply and discharging amounts (flow rates) under a CPU control signal.

Although not shown in FIG. 9, the density sensors Ds2, Ds3 and Ds4 are provided in the purge pipes 82A, 82B and 82C, respectively, like shown in FIG. 7, for detecting the density of resist solvent. These sensors may be installed in the buffers 59A, 59B and 59C.

Instead of the density sensors Ds2, Ds3 and Ds4, the optical film-thickness sensors FTs2, FTs3 and FTs4 (also not shown in FIG. 9) may be provided like shown in FIGS. 7 and 8 with the light source Ls, to detect an average film thickness of a resist film formed on each wafer W.

The PB unit in the third embodiment also achieves control of evaporation rate of solvent remaining on each wafer W with control of gas discharging amount (flow rate) in accordance with resist-solvent density detected by the density sensors Ds2, Ds3 and Ds4 or the film thickness detected by the optical film-thickness sensors FTs2, FTs3 and FTs4.

In detail, the supply of solvent gas is switched to discharging from wafer-surface regions on which a large amount of solvent remains in the resist film, for effective gas replacements in the processing chamber 50 to promote solvent evaporation. On the contrary, a specific density of solvent gas is supplied onto wafer-surface regions on which a small amount of solvent remains in the resist film, to restrict solvent evaporation.

Therefore, the third embodiment achieves accurate adjustments to process gas in the processing chamber 50 and also control of evaporation rate of solvent remaining on each wafer W.

The third embodiment disclosed above is equipped with the mixers 77A, 77B and 77C connected to the gas supply pipes 72A, 72B and 72C, respectively, for supply of solvent gas into the processing chamber 50 at required density.

It is, however, possible that the mixers 77A, 77B and 77C, and the solvent sources 79A, 79B and 79C are omitted while the gas supply sources 78A, 78B and 78C are only connected to the gas supply pipes 72A, 72B and 72C, respectively, for supply of inert gas such as N₂ or dry air.

Moreover, the third embodiment disclosed above is equipped with the three-way valves 83A, 83B and 83C for gas supply and discharging through the supply and exhaust openings 81A, 81B and 81C, respectively.

It is, however, possible to provide several exhaust openings and supply openings separately instead of the supply and exhaust openings 81A, 81B and 81C, for gas supply and discharging control under the CPU 100, without the three-way valves 83A, 83B and 83C.

The embodiments disclosed above are applied to processing of semiconductor wafers. Not only that, the present invention is also applicable to other substrates such as LCD substrates and photo-mask reticle substrates.

As disclosed above in detail, the present invention has the following advantages:

(1) The thermal processing apparatus in each embodiment according to the present invention includes a processing chamber containing a heat source and a table on which a substrate having a processed film thereon is to be placed.

(2) The thermal processing apparatus in an embodiment according to the present invention includes a discharger for discharging process gas from the processing chamber and a ceiling plate provided between the substrate and the discharger, having apertures at different aperture ratios in accordance with distances from the center of the ceiling plate, in addition to the components in (1). The ceiling plate may be made of a porous material with different aperture ratios in accordance with distances from the center of the material.

The thermal processing apparatus in (2) can discharge process gas at different discharging amounts through the ceiling plate, thus capable of controlling evaporation rate of solvent on the concentric circles of the substrate for uniformity of solvent amount remaining on the substrate, and hence achieving uniformity of pattern width.

(3) The thermal processing apparatus in another embodiment according to the present invention includes a plurality of dischargers, provided over concentric circles of the substrate, for discharging process gas from the processing chamber and a plurality of discharging-amount adjusters each for adjusting a discharging amount of the corresponding discharger, in addition to the components in (1).

The thermal processing apparatus in (3) can discharge process gas at different discharging amounts through the discharges and discharging-amount adjusters, thus capable of controlling evaporation rate of solvent on the concentric circles of the substrate for uniformity of solvent amount remaining on the substrate, and hence achieving uniformity of pattern width.

(4) The thermal processing apparatus in further embodiment according to the present invention includes a plurality of dischargers, provided over concentric circles of the substrate, for discharging process gas from the processing chamber, a plurality of gas suppliers, provided over the concentric circles of the substrate, for supplying process gas into the processing chamber, a plurality of discharging-amount adjusters each for adjusting a discharging amount of the corresponding discharger and a plurality of supply-amount adjusters each for adjusting a supply amount of the corresponding supplier, in addition to the components in (1).

(5) The thermal processing apparatus in still another embodiment according to the present invention includes a plurality of supply and discharging units, provided over concentric circles of the substrate, for supplying and discharging process gas into and from the processing chamber, a switch for switching the supply and discharging units between the supplying and discharging of the process gas, a plurality of supply-amount adjusters each for adjusting a supply amount of the corresponding supply and exhaust unit and a plurality of discharging-amount adjusters each for adjusting a discharging amount of the corresponding supply and discharging unit, in addition to the components in (1).

The thermal processing apparatus in (4) and (5) are capable of controlling evaporation rate of solvent on the concentric circles of the substrate with effective supply and discharging of process gas to and from the processing chamber for uniformity of solvent amount remaining on the substrate, and hence achieving uniformity of pattern width.

(6) The thermal processing apparatus in (4) are (5) may further include a gas-density adjuster for adjusting density of solvent for the process gas supplied by each supplier or each supply and discharging unit.

The thermal processing apparatus in (6) is capable of controlling evaporation rate of solvent on the concentric circles of the substrate with adjustments to density of solvent for the process gas in the processing chamber for uniformity of solvent amount remaining on the substrate, and hence achieving uniformity of pattern width.

(7) The thermal processing apparatus in (3) may further include a plurality of buffers to face the substrate under the dischargers, for providing uniform gas pressure over the concentric circles of the substrate. Such buffers may be applied to the thermal processing apparatus in (4) so as to face the substrate under the dischargers or the suppliers. Such buffers may further be applied to the thermal processing apparatus in (5) so as to face the substrate under the supply and discharging units.

The thermal processing apparatus with these buffers are capable of controlling evaporation rate of solvent on the concentric circles of the substrate with adjustments to solvent for the process gas in the processing chamber for uniformity of solvent amount remaining on the substrate, and hence achieving uniformity of pattern width.

Moreover, thermal processing apparatus in (3), (4) and (5) may further include density sensors for detecting the density of resist solvent or an optical film-thickness sensor (or more sensors) for detecting an average film thickness of a resist film formed on each wafer.

These sensors offer more accurate control of evaporation rate of solvent remaining on each wafer with control of gas discharging amount (flow rate) in accordance with detected resist-solvent density or film thickness.

What is claimed is:

1. A thermal processing apparatus including a processing chamber containing a heat source and a table for a substrate having a processed film thereon to be placed thereon, comprising:
a discharger for discharging process gas from the processing chamber; and
a ceiling plate provided between the substrate and the discharger, having apertures at different aperture ratios in accordance with distances from the center of the ceiling plate.

2. The thermal processing apparatus according to claim 1, wherein the ceiling plate is made of a porous material with different aperture ratios in accordance with distances from the center of the material.

3. A thermal processing apparatus including a processing chamber containing a heat source and a table for a substrate having a processed film thereon to be placed thereon, comprising:
a plurality of dischargers, provided over concentric circles of the substrate, for discharging process gas from the processing chamber; and
a plurality of discharging-amount adjusters each for adjusting a discharging amount of the corresponding discharger.

4. The thermal processing apparatus according to claim 3 further comprising a plurality of buffers so as to face the substrate under the dischargers, for providing uniform gas pressure over the concentric circles of the substrate.

5. The thermal processing apparatus according to claim 3 further comprising a density sensor provided along each discharger, for detecting density of solvent for the processed film, wherein each discharging-amount adjuster adjusts the discharging amount of the corresponding discharger in accordance with the density detected by the density sensor.

6. The thermal processing apparatus according to claim 4 further comprising a density sensor provided in each buffer, for detecting density of solvent for the processed film, wherein each discharging-amount adjuster adjusts the discharging amount of the corresponding discharger in accordance with the density detected by the density sensor.

7. The thermal processing apparatus according to claim 4 further comprising at least one optical film-thickness sensor provided in one of the buffers, for detecting a thickness of the processed film, wherein each discharging-amount adjuster adjusts the discharging amounts of the corresponding discharger in accordance with the film thickness detected by the density sensor.

8. A thermal processing apparatus including a processing chamber containing a heat source and a table on which a substrate having a processed film thereon is to be placed, comprising:
a plurality of dischargers, provided over concentric circles of the substrate, for discharging process gas from the processing chamber;
a plurality of gas suppliers, provided over the concentric circles of the substrate, for supplying process gas into the processing chamber;
a plurality of discharging-amount adjusters each for adjusting a discharging amount of the corresponding discharger; and
a plurality of supply-amount adjusters each for adjusting a supply amount of the corresponding supplier.

9. The thermal processing apparatus according to claim 8 further comprising a gas-density adjuster for adjusting density of process gas supplied to each supplier.

10. The thermal processing apparatus according to claim 8 further comprising a plurality of buffers so as to face the substrate under the dischargers or the suppliers, for providing uniform gas pressure over the concentric circles of the substrate.

11. The thermal processing apparatus according to claim 8 further comprising a density sensor provided along each discharger or supplier, for detecting density of solvent for the processed film, wherein each discharging-amount adjuster adjusts the discharging amount of the corresponding discharger or each supply-amount adjuster adjusts the supply amount of the corresponding supplier, in accordance with the density detected by the density sensor.

12. The thermal processing apparatus according to claim 10 further comprising a density sensor provided in each buffer, for detecting density of solvent for the processed film, wherein each discharging-amount adjuster adjusts the discharging amount of the corresponding discharger or each supply-amount adjuster adjusts the supply amount of the corresponding supplier, in accordance with the density detected by the density sensor.

13. The thermal processing apparatus according to claim 8 further comprising at least one optical film-thickness sensor provided over the substrate, for detecting a thickness of the processed film, wherein each discharging-amount adjuster adjusts the discharging amount of the corresponding discharger or each supply-amount adjuster adjusts the supply amount of the corresponding supplier, in accordance with the film thickness detected by the density sensor.

14. A thermal processing apparatus including a processing chamber containing a heat source and a table for a substrate having a processed film thereon to be placed thereon, comprising:
a plurality of supply and discharging units, provided over concentric circles of the substrate, for supplying and discharging process gas into and from the processing chamber;
a switch for switching the supply and discharging units between the supplying and discharging of the process gas;
a plurality of supply-amount adjusters each for adjusting a supply amount of the corresponding supply and exhaust unit; and
a plurality of discharging-amount adjusters each for adjusting a discharging amount of the corresponding supply and discharging unit.

15. The thermal processing apparatus according to claim 14 further comprising a gas-density adjuster for adjusting density of a solvent for the process gas supplied by each supply and discharging unit.

16. The thermal processing apparatus according to claim 14 further comprising a plurality of buffers so as to face the substrate under the supply and discharging units, for providing uniform gas pressure over the concentric circles of the substrate.

17. The thermal processing apparatus according to claim 14 further comprising a density sensor provided in each supply and discharging unit, for detecting density of solvent for the processed film, wherein each discharging-amount adjuster adjusts the discharging amount of the corresponding supply and discharging unit or each supply-amount adjuster adjusts the supply amount of the corresponding supply and discharging unit, in accordance with the density detected by the density sensor.

18. The thermal processing apparatus according to claim 16 further comprising a density sensor provided in each buffer, for detecting density of solvent for the processed film, wherein each discharging-amount adjuster adjusts the discharging amount of the corresponding supply and discharging unit or each supply-amount adjuster adjusts the supply amount of the corresponding supply and discharging unit, in accordance with the density detected by the density sensor.

19. The thermal processing apparatus according to claim 14 further comprising at least one optical film-thickness sensor over the substrate, for detecting a thickness of the processed film, wherein each discharging-amount adjuster adjusts the discharging amount of the corresponding discharger each supply-amount adjuster adjusts the supply amount of the corresponding supply and discharging unit, in accordance with the film thickness detected by the density sensor.
